(19) United States
(12) Patent Application Publication
(10) Pub. No.: US 2007/0261735 A1
(43) Pub. Date: Nov. 15, 2007

(54) Liquid Amount Monitoring Apparatus, Semiconductor Manufacturing Apparatus Having the Liquid Amount Monitoring Apparatus Mounted Thereon, and Liquid Material/Liquid Amount Monitoring Method

(76) Inventors: Akira Yasumuro, Nirasaki-shi (JP); Hachishiro Iizuka, Amagasaki-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/577,456

(22) PCT Filed: Oct. 18, 2005
(86) PCT No.: PCT/JP05/19136

§ 371 Date: Apr. 18, 2007

(30) Foreign Application Priority Data
Oct. 18, 2004 (JP) 2004-302563

(51) Int. Cl. B01J 4/00; H01L 21/56

(52) U.S. Cl. 137/154; 438/780

(57) ABSTRACT

A semiconductor manufacturing apparatus includes a container (Xb, Ab, Bb, or Cb) for receiving a liquid material, a liquid material supply section for supplying the liquid material from the container, a liquid vaporizing section for vaporizing the liquid material supplied from the liquid material supply section to generate a gas, a processing section for using the gas supplied from the liquid vaporizing section to execute deposition processing, an exhaust section for exhausting a gas from the processing section, and a liquid level detector (Xs, As, Bs, or Cs) arranged in a bottom of the container to detect a liquid level of the liquid material based on an acoustic wave.

### TECHNICAL FIELD

The present invention relates to a liquid amount monitoring technology suitable for a semiconductor manufacturing apparatus which forms a film by using an organic liquid material containing an organic raw material solution.

### BACKGROUND ART

There is generally available a CVD apparatus which uses a raw material vaporizing supply system for vaporizing a liquid material such as a liquid organic metal or an organic metal solution. The liquid material includes not only a case in which a raw material itself is a liquid but also a case of a raw material solution of a state in which a solid or liquid raw material is dissolved in a solvent.

The CVD apparatus is configured to supply a liquid material from a container to a carburetor, vaporize the liquid material by the carburetor to guide a gas to a deposition chamber, and form a thin film on a substrate in the deposition chamber.

For example, such a CVD apparatus is described in Jpn. Pat. Appln. KOKAI Publication No. 7-268634. The CVD apparatus receives a liquid material in a container, and applies pressure to the container through a pressure line connected to the container to extrude the liquid material to a liquid supply line connected to the container. A predetermined amount of a liquid material is supplied into a processing chamber by a flow rate controller of a liquid material supply section disposed in the liquid supply line.

In the liquid material supply section, a remaining amount of the liquid material in the container is managed, and the container must be replaced with a container filled with a raw material before the liquid material runs out. For example, a configuration example of such a liquid material supply section is disclosed in Jpn. Pat. Appln. KOKAI Publication No. 2002-095955.

Conventionally, a method that uses a liquid level sensor such as a float type residual amount gauge has been used for detecting the amount of a liquid in the container. However, in the case of the liquid material used for the CVD, a general liquid level sensor installed in the container cannot be used because of chemical resistance of a sensor section, a deterioration in detection accuracy caused by raw material sticking to the sensor section, raw material contamination by the sensor section, or a danger of flashing of the liquid material.

Accordingly, as described in Jpn. Pat. Appln. KOKAI Publication No. 2002-095955, in the CVD apparatus, the residual amount of a liquid material in the container is estimated from a flow rate setting value or a flow rate detection value of the flow rate controller. In other words, the amount of a used liquid is calculated based on a flow rate integrated value of the liquid material or a product of a flow rate of the liquid material and supply time, and a residual liquid amount in the container is obtained based on the amount of a used liquid.

### DISCLOSURE OF INVENTION

In the case of the aforementioned method for calculating the used liquid amount or the liquid residual amount, a difference between the calculated liquid residual amount and an actual liquid residual amount is larger as flow rate integrated time is longer. Accordingly, even when actually raw materials still remain, the container may be changed based on the calculated liquid residual amount in consideration of safety. To change the container in which raw materials still remain means wasteful discarding of the very expensive liquid material, causing a problem of an increase in operation costs.

When the method for calculating the liquid residual amount, an error of residual amount displaying is larger as a reception volume of the container is increased more. Thus, it is difficult to reduce a discarding amount of the liquid material by the enlargement of the container.

As another method, a residual amount of the liquid material may be measured based on a weight change of the container. However, as the container is normally connected to a pipe or the like, a weight of the container cannot be measured, and a detection error is large making it impossible to accurately know the liquid residual amount.

The present invention provides a liquid amount monitoring apparatus which meets requirements of prevention of contamination by a received liquid raw material and chemical resistance and accurately detects a residual amount of the liquid raw material received in the container, a semiconductor manufacturing apparatus which includes the liquid amount monitoring apparatus, and a liquid material/liquid amount monitoring method.

The present invention provides a semiconductor manufacturing apparatus including a liquid material supply section which includes a container for receiving a liquid material and supplies the liquid material from the container, a liquid vaporizing section which vaporizes the liquid material supplied from the liquid material supply section to generate a gas, a processing section which executes processing by using the gas supplied from the liquid vaporizing section, an exhaust section which exhausts the gas from the processing section, and a liquid level detector arranged in a bottom of the container to introduce an acoustic wave into the liquid material and to detect a liquid level of the liquid material from a reflected wave reflected on a liquid surface.

The present invention provides a liquid amount monitoring apparatus including a container for receiving a liquid material, a liquid supply line connected to the container, a flow rate controller or a flow rate detector disposed in the midway of the liquid supply line, a liquid level detector arranged in a bottom of the container to introduce an acoustic wave into the liquid material and to detect a liquid level of the liquid material from a reflected wave reflected on a liquid surface, liquid amount calculation means for calculating a used liquid amount or a liquid residual amount in the container based on a flow rate setting value for the flow rate controller or a flow rate detection value by the flow rate detector, and liquid amount correction means for correcting the used liquid amount or the liquid residual amount calculated by the liquid amount calculation means based on the liquid level detection value detected by the liquid level detector

The present invention provides a liquid amount monitoring method of a semiconductor manufacturing apparatus which sends a liquid material from a container for receiving the liquid material and vaporizes the liquid material to generate a gas, and sends the gas to a processing section to execute processing, characterized by introducing an acoustic wave from a bottom of the container into the liquid material, detecting a liquid level of the liquid material from a reflected wave reflected on a liquid surface, and using a detected liquid level detection value to check a residual amount of the liquid material in the container.

The present invention provides a liquid amount monitoring method for monitoring a liquid in a container in a process of supplying the liquid via a liquid supply line connected to the container for receiving the liquid, characterized by calculating a used liquid amount or a liquid residual amount in the container based on a flow rate of the liquid through the liquid supply line, arranging a liquid level detector for detecting a liquid level of the liquid based on an acoustic wave in a bottom of the container, and correcting the used liquid amount or the liquid residual amount based on a liquid level detection value detected by the liquid level detector.

### BRIEF DESCRIPTION OF DRAWINGS

FIG. 1 is a schematic configuration diagram showing an entire configuration of a semiconductor manufacturing apparatus according to an embodiment of the present invention.

FIG. 2 is a schematic configuration diagram showing a configuration of a liquid material supply section of the embodiment.

FIG. 3 is a schematic configuration diagram showing a configuration of a main section of a control system of the embodiment.

FIG. 4 is a longitudinal sectional diagram showing a container structure of the embodiment.

FIG. 5 is an enlarged partial sectional diagram of a container bottom of the embodiment.

FIG. 6 is a graph showing a detected waveform example of a liquid level detector of the embodiment.

FIG. 7 is a timing chart showing operation timing of each section of the embodiment,

FIG. 8 is a schematic flowchart showing a procedure of a liquid amount monitoring program of the embodiment.

### BEST MODE FOR CARRYING OUT THE INVENTION

The preferred embodiments of the present invention will be described below in detail with reference to the accompanying drawings.

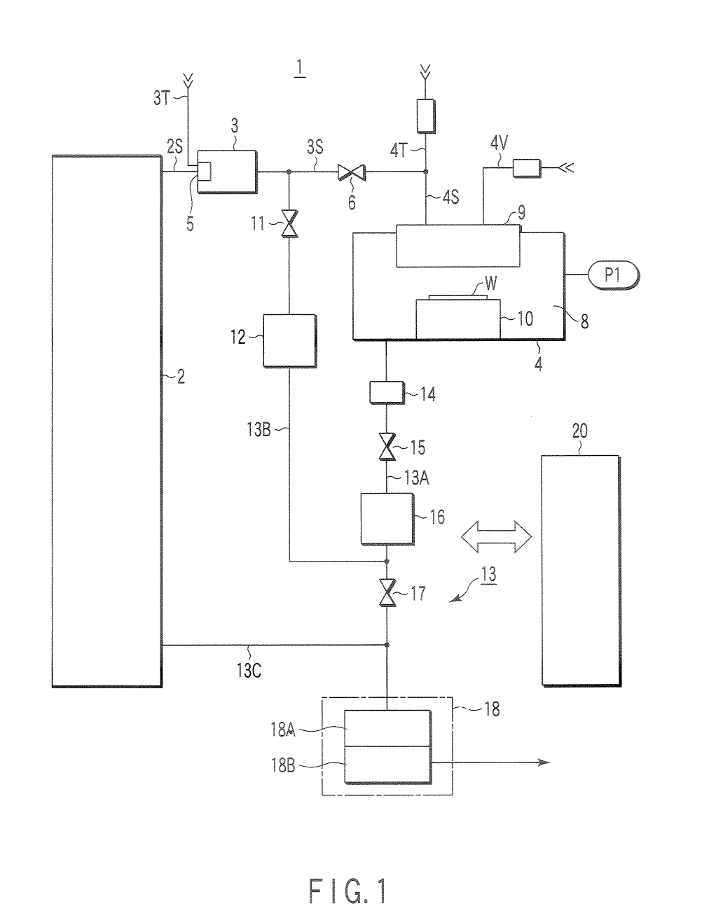

Embodiments of a semiconductor manufacturing apparatus, a liquid amount monitoring apparatus, a liquid material monitoring method, and a liquid amount monitoring method according to the present invention will be described. FIG. 1 is a schematic configuration diagram showing an entire configuration of a semiconductor manufacturing apparatus 1 of an embodiment.

According to the embodiment, as the semiconductor manufacturing apparatus 1, an MOCVD apparatus equipped with a liquid material vaporizing supply system for vaporizing and supplying a liquid organic metal or an organic metal solution which becomes a liquid material is taken as an example. It should be noted that the semiconductor manufacturing apparatus of the present invention can be applied to various semiconductor manufacturing apparatuses other than the MOCVD apparatus, for example, various CVD apparatuses such as a batch type and a sheet-fed type using a liquid material other than an organic metal raw material, or various semiconductor manufacturing apparatuses such as a dry etching apparatus.

[Apparatus Configuration]

The semiconductor manufacturing apparatus 1 includes a liquid material supply section 2 for supplying a liquid material such as a liquid organic metal or an organic metal solution, a carburetor (liquid vaporizing section) 3 for vaporizing the liquid material supplied from the liquid material supply section 2 to generate a gas, a processing chamber 4 for executing deposition based on the gas supplied from the carburetor 3, an exhaust section 13 for exhausting a gas from the carburetor 3, the processing chamber 4 or the liquid material supply section 2, and a control section 20 for controlling the entire apparatus including these components.

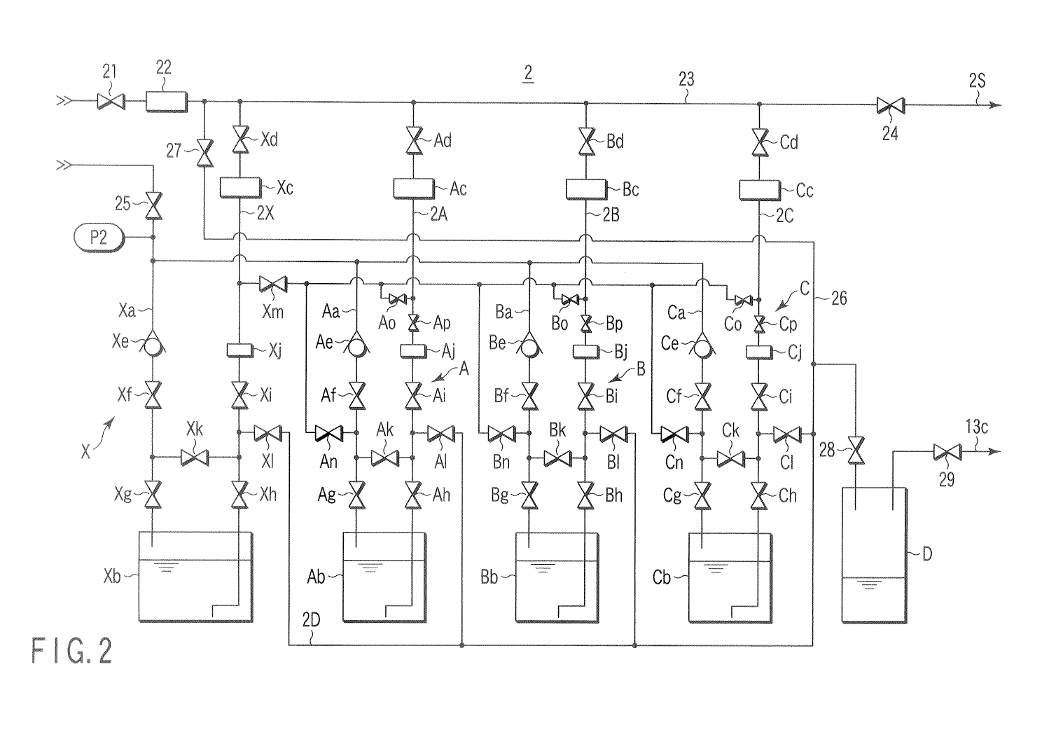

FIG. 2 shows a configuration example of the liquid material supply section 2.

The liquid material includes not only a case in which a raw material is a liquid but also a case of a raw material solution in a state in which a solid or liquid raw material is dissolved in a solvent. A container filled with or receiving a solvent or a raw material which is a liquid material is called a solvent container, a raw material container, or simply a container.

The liquid material supply section 2 includes a solvent supply section X, an A material supply section, a B material supply section and a C material supply section. The solvent supply section X includes a pressure line Xa for supplying a pressure gas such as an inactive gas to a solvent container Xb, the solvent container Xb for receiving an organic solvent, and a supply line 2X for supplying the organic solvent from the solvent container Xb.

The A material supply section includes a similar pressure line Aas, a raw material container Ab for receiving a liquid organic raw material or an organic raw material solution, and a supply line 2A for supplying a liquid material from the raw material container Ab. The B material supply section includes a similar pressure line Ba, a raw material container Bb for receiving a liquid organic raw material or an organic raw material solution, and a supply line 2B for supplying a liquid material from the raw material container Bb. The C material supply section includes a similar pressure line Ca, a raw material container Cb for receiving a liquid organic raw material or an organic raw material solution, and a supply line 2C for supplying a liquid material from the raw material container Cb. According to the embodiment, the solvent container or the raw material container normally has a volume of about 0.5 to 50 litters.

When the semiconductor manufacturing apparatus 1 is used to form a high dielectric thin film (high-k material) such as PZT (Pb[Zrl-xTix]O₃), butyl acetate or the like is used as an organic solvent which is one of liquid materials. For the liquid material supplied from the A material supply section, an organic Pb raw material such as Pb(DPM)₂ can be used. For the liquid material supplied from the B material supply section, an organic Zr raw material such as Zr(O-t-Bu)₄ can be used. For the liquid material supplied from the material supply section, an organic Ti raw material such as Ti(O-i-Pr)₄ can be used. The present invention is not limited to the aforementioned organic liquid materials. But various liquid materials can be used, for example, liquid materials for deposition of other high-k film materials as BST, STO, BTO, SBT and ZrO can be used and TiCl₄ is used as an inorganic liquid material when TiN is deposited.

In the solvent supply section X, the A material supply section, the B material supply section, and the C material supply section, the supply lines 2X, 2A, 2B and 2C are connected to a raw material mixing section 23. In the supply lines 2X, 2A, 2B and 2C, open/close valves Xh, Ah, Bh and Ch, open/close valves Xi, Ai, Bi, and Ci, filters Xj, Aj, Bj, and Cj, open/close valves Ap, Bp, and Cp, flow rate controllers Xc, Ac, Bc and Cc constituted of mass flowmeters, flow rate control valves or the like, and open/close valves Xd, Ad, Bd and Cd are sequentially arranged toward a downstream side. In the pressure lines Xa, Aa, Ba, and Ca, check valves Xe, Ae, Be, and Ce, open/close valves Xf, Af, Bf, and Cf, and open/close valves Xg, Ag, Bg, and Cg are sequentially arranged toward the downstream side.

Branch places between the open/close valves Xf, Af, Bf, and Cf and the open/close valves Xg, Ag, Bg and Cg in the pressure lines Xa, Aa, Ba and Ca and branch places between the open/close valves Xi, Ai, Bi and Ci and the open/close valves Xh, Ah, Bh and Ch in the supply lines 2X, 2A, 2B and 2C are connected together via open/close valves Xk, Ak, Bk and Ck. Branch places between the open/close valves Xi, Ai, Bi and Ci and the open/close valves Xh, Ah, Bh and Ch in the supply lines 2X, 2A, 2B and 2C are connected to an exhaust line 2D via open/close valves Xl, Al, Bl and Cl. A branch place between a filter Xj and a flow rate controller Xc in the supply line 2X is passed through an open/close valve Xm to be connected to the pressure lines Aa, Ba and Ca via An, Bn and Cn. Similarly, it is passed through the open/close valve Xm to be connected to the supply lines 2A, 2B and 2C via Ao, Bo, and Co.

Upstream places of the pressure lines Xa, Aa, Ba and Ca are connected to one another, and connected to a pressure gas source such as an inactive gas via an open/close valve 25. A pressure gauge P2 is disposed on a downstream side of the open/close valve 25. The exhaust line 2D is connected to a bypass line 26, and connected to the raw material mixing section 23 via an open/close valve 27. A downstream end of the raw material mixing section 23 is connected to a raw material supply line 2S for introduction into the carburetor 3 via an open/close valve 24. An upstream end of the raw material mixing section 23 is connected to a carrier gas source such as an inactive gas via an open/close valve 21 and a flow rate controller 22. The exhaust line 2D is connected to a drain tank D via an open/close valve 28, and the drain tank D is connected to a raw material supply exhaust line 13C via an open/close valve 29.

As shown in FIG. 1, the carburetor 3 includes a spray nozzle 5 to which the raw material supply line 2S derived from the liquid material supply section 2 and a spray gas line 3T for supplying a spray gas such as an inactive gas are connected. The spray nozzle 5 spays liquid material mist into the heated carburetor 3, and vaporizes the liquid material to generate a raw material gas. The carburetor 3 is connected to a gas supply line 3S. The gas supply line 3S is connected to the processing chamber 4 via a gas introduction valve 6.

A carrier gas supply line 4T for supplying a carrier gas such as Ar inactive gas is connected to the gas supply line 3S, and the carrier gas can be introduced into the processing chamber 4 via the gas supply line 4S.

For example, the processing chamber 4 is a tightly sealed container made of a metal such as aluminum, and its inside is a deposition chamber 8 for executing deposition processing. The deposition chamber 8 includes a gas introduction section 9 to which the gas supply line 4S for supplying a raw material gas and a reactive gas line 4V for supplying an oxidizing reactive gas such as O₂, O₃ or NO₂ are connected The gas introduction section 9 has a shower head structure for introducing a raw material gas and a reactive gas from very small holes into the deposition chamber 8.

The deposition chamber 8 includes a susceptor 10 arranged to face the gas introduction section 9. A substrate W which becomes a processing target is mounted on the susceptor 10. A pressure gage P1 measures pressure in the deposition chamber 8.

The exhaust section 13 includes a main exhaust line 13A connected to the deposition chamber 8. In the main exhaust line 13A, a pressure adjust valve 14, an open/close valve 15, an exhaust trap 16m and an open/close valve 17 are sequentially arranged toward the downstream side.

The pressure adjust valve 14 has a function of adjusting the pressure in the deposition chamber 8, and constitutes automatic pressing adjusting means. The pressure adjust valve 14 controls an opening/closing degree of the valve in accordance with detected pressure of the pressure gauge P1, and automatically adjusts the pressure in the deposition chamber 8 to be equal to a set value. The exhaust section 13 includes a bypass exhaust line 13B connected between the gas supply line 3S and the main exhaust line 13A. An upstream end of the bypass exhaust line 13B is connected between the carburetor 3 and the gas introduction valve 6, and its downstream end is connected between the exhaust trap 16 and the open/close valve 17. In the bypass exhaust line 13B, an open/close valve 11 and an exhaust trap 12 are sequentially arranged toward the downstream side.

The exhaust section 13 includes a raw material supply exhaust line 13C derived from the liquid material supply section 2. The raw material supply exhaust line 13C is connected between the open/close valve 17 of the main exhaust line 13A and an exhaust device 18. The exhaust device 18 is serially arranged in two stages. For example, a main exhaust pump 18A for evacuating the processing chamber 4 from a low vacuum degree to a high vacuum degree is a mechanical booster pump, and an exhaust pump 18B of a next stage for evacuation from atmospheric pressure to a low vacuum degree and receiving back pressure of the main exhaust pump 18A is a dry pump.

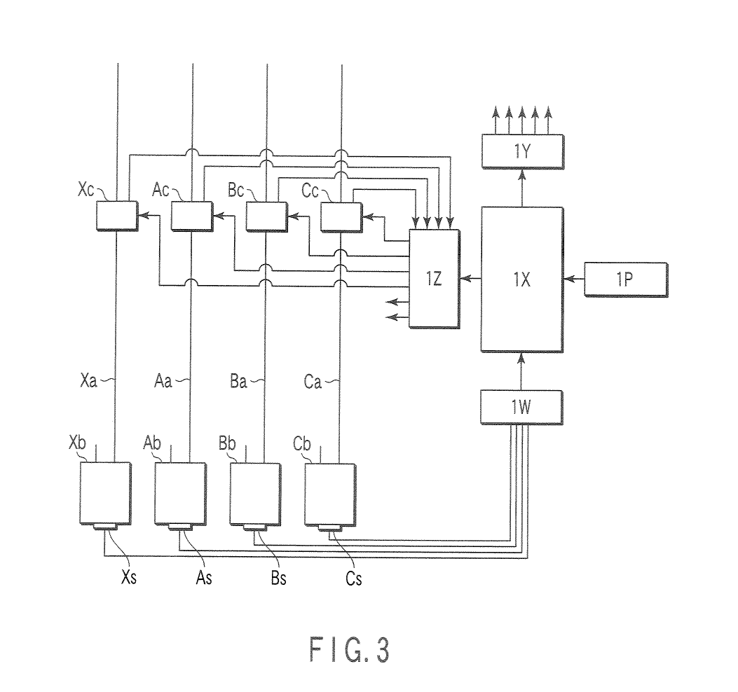

FIG. 3 is a schematic configuration diagram showing a configuration of a main section of a control system of the embodiment.

The control section 20 of the embodiment includes a control section (arithmetic processing section) 1X constituted of a microprocessing unit (MPU) or the like, and an operation section 1P, an open/close valve control section 1Y, a flow rate control section 1Z and a liquid level measuring unit 1W which are connected to the control section 1X

Among these components, the operation section 1P includes, e.g., a keyboard, a touch panel or the like, and executes various input operation to the control section 1X. The open/close valve control section 1Y controls the open/close valve disposed in each section of the apparatus. The flow rate control section 1Z receives a signal from a flow rate detector to control a flow rate controller disposed in each section of the apparatus. The flow rate control section 1Z sets flow rates based on flow rate detection values output from the flow rate controllers Xc, Ac, Bc and Cc. For example, each of the flow rate controllers Xc, Ac, Bc and Cc includes a flow rate detector such as a mass flowmeter (MFM) and a flow rate adjust valve such as a highly accurate flow rate variable valve.

The liquid level measuring section 1W controls a liquid level detector disposed in the apparatus to detect a liquid level. The liquid level measuring section 1W of the embodiment is connected to liquid level detectors Xs, As, Bs, and Cs firmly fixed in the bottoms of the containers Xb, Ab, Bb and Cb from the outside. The liquid detectors Xs, As, Bs and Cs detects liquid levels of solvents or liquid materials in the containers Xb, Ab, Bb and Cb based on acoustic waves. In other words, these liquid level detectors Xs, As, Bs and Cs are configured to detect liquid levels by introducing acoustic waves into the liquids via bottom walls of the containers, advance the acoustic waves through the liquid to be reflected on liquid surfaces, and detecting reflected waves thereby generated. The liquid level detectors Xs, As, Bs and Cs will be described below in detail.

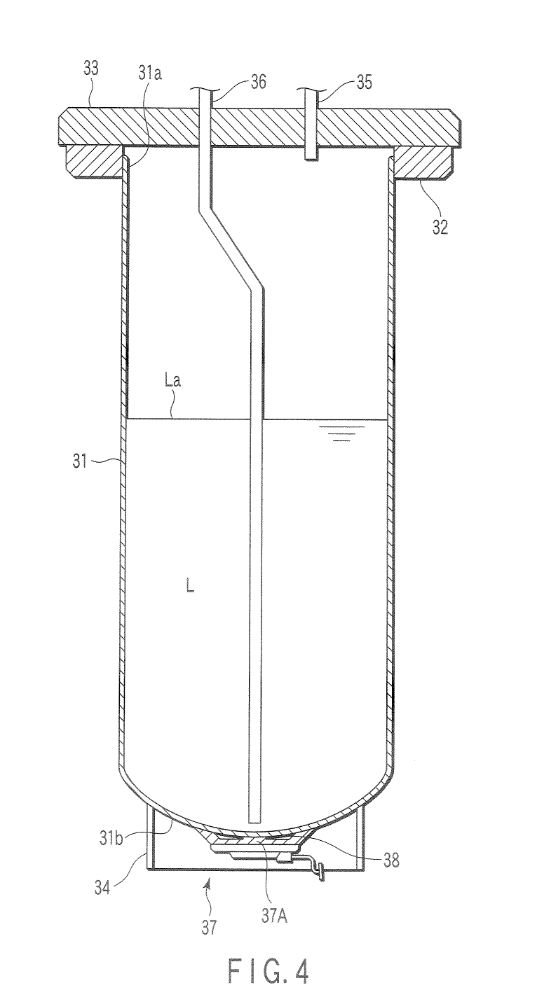

FIG. 4 is a schematic sectional diagram showing a structure of each of the containers Xb, Ab, Bb and Cb of the embodiment.

The container includes a body 31 having a cylindrical body and a bottom made of stainless steel (SUS 316) or the like. A flange 32 having a detachable cap 33 is fixed (fixed by welding) to an opening edge of an upper opening 31a of the body 31. A pressure pipe 35 connected to the pressure lines Xa, Aa, Ba and Ca and a supply pipe 36 connected to the supply lines 2X, 2A, 2B and 2C penetrate the cap 33 to be fixed. The pressure pipe 35 is arranged to open in an upper part of the body 31, and the supply pipe 36 is arranged to open near an inner bottom of the body 31.

A bottom 31b of the body 31 is preferably formed into a convex curve shape toward the outside to effectively feed the liquid material. Needless to say, the bottom is not limited to the convex curve shape, but it may be a flat surface. A detector main body 37 constituting each of the liquid detectors Xs, As, Bs and Cs is fixed to the bottom 31b of the body 31. The detector main body 37 includes an excitation section 37A constituted of a piezoelectric vibrator or the like, and a temperature detection section (not shown) disposed inside (center) the excitation section 37A. The detector main body 37 includes a support section to mount and support the bottom 31b to an outer periphery of the excitation section 37A. For example, The support section can detachably fix the detector main body 37 to the bottom 31b by bolt fixing or magnet attraction. Additionally, for example, the detector main body 37 may be tightly bonded to the body 31 by a elastic member such as a pressure spring interposed between the main body 37 and a holding frame fixed to the body 31. Preferably, a gel sound transmission agent 38 such as grease or a gel sheet is applied on a contact surface between the bottom 31b and the support section to tightly bond them together. The sound transmission agent 38 can highly efficiently propagate and introduce an ultrasonic wave generated at the excitation section 37A into the body 31. An annular leg 34 is disposed in the bottom 31b of the body 31. The body 34 has a function of fixing the body to an installation place, and protecting the detector main body 37 when installed.

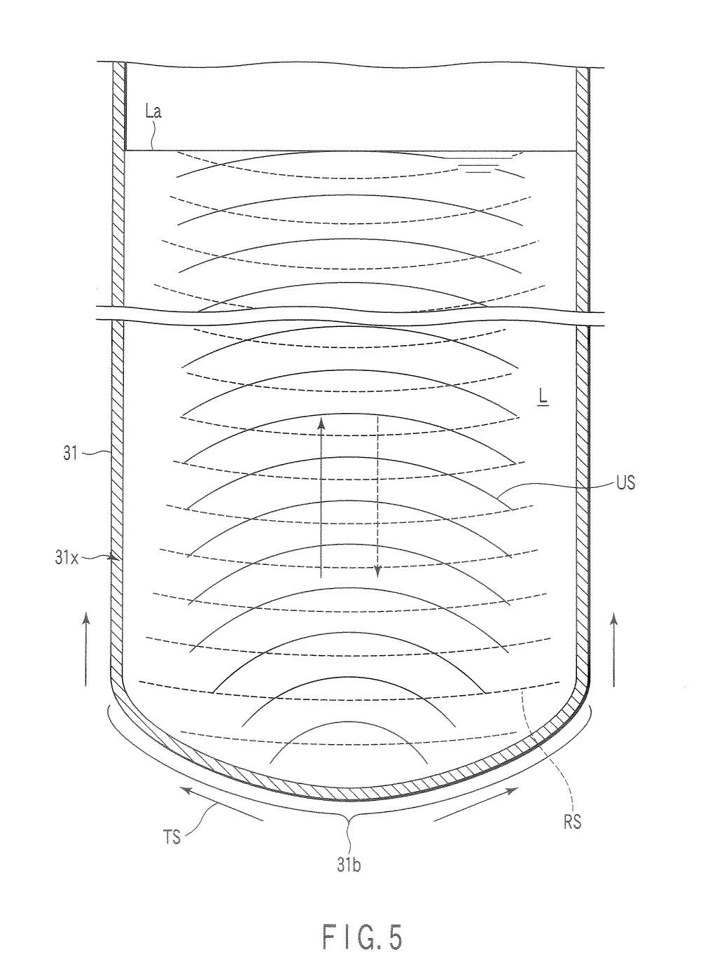

FIG. 5 is an enlarged partial sectional diagram showing an enlarged lower part (bottom 31b side) of the body 31. In the detector main body 37, an AC voltage is applied to a piezoelectric body or the like disposed in an oscillation section (not shown) to induce vibration in the excitation section 37A within a predetermined period. After the passage of the predetermined period, driving of the excitation section 37A is stopped, and the excitation state 37A is set in a free vibrating state.

The vibration of the excitation section 37A generates an acoustic wave (ultrasonic wave) US which enters the bottom 31b of the body 31. The acoustic wave US is propagated through the liquid L received inside through the bottom wall of the bottom 31b to be directed toward a liquid surface La located above.

Then, the acoustic wave US is reflected on the liquid surface La, and a reflected wave RS is propagated downward through the liquid L. The reflected wave RS vibrates the excitation section 37A through the bottom wall. The detector main body 37 receives this vibration by a reception section (not shown) to generate a electric potential from the piezoelectric body disposed in the reception section. A position of the liquid surface La can be known from the electric potential.

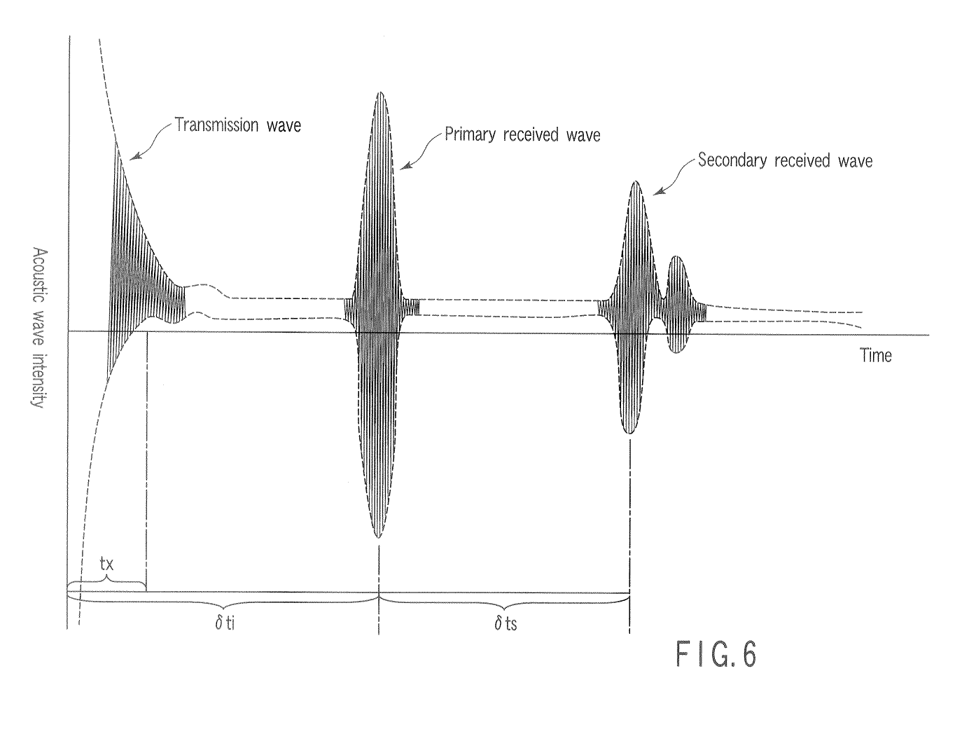

FIG. 6 is a graph showing a waveform of an acoustic wave when the acoustic wave US is applied into the body 31 as described above and its reflected wave RS is received The acoustic wave is indicated by a solid line while being partially omitted, and an envelope of the acoustic wave is indicated by a dotted line in the drawing.

A frequency of the acoustic wave US is 50 kHz to 1 MHz. In FIG. 6, primary and secondary reception waves are sequentially detected after a transmission wave. The following is established:
Liquid level (height of liquid surface) LH=VL×(δti−2d/VS)/2
where δti is time from generation of a transmission wave to detection of a primary reception wave (primary reflected wave), δts is time from detection of a primary wave to detection of a secondary reception wave (secondary reflected wave), VL is a speed (acoustic velocity) of the acoustic wave in the liquid L, VS is a speed (acoustic velocity) of the acoustic wave in the body 31, and d is a thickness of a wall surface of the bottom 31b of the body 31.

Thus, the liquid level LH can be measured by measuring δti. The method provides high sensitivity in an area of a high liquid level LH. In this case, the liquid level LH becomes lower and the detection time δti becomes shorter when the liquid surface La is reduced. When the detection time δti is shorter than tx, the primary reception wave cannot be discriminated from a transmission wave itself or a detected noise (reverberation of transmission wave or acoustic wave caused by reflection or the like other than liquid surface La), disabling detection of the primary reception wave.

When liquid level LH=VL×(δts−2d/VS)/4 is established, the liquid level LH can be obtained by measuring δts of a secondary reflected wave. The method provides high sensitivity in an area of a low liquid level LH. In this case, when a rise in the liquid surface La causes the liquid level LH to be excessively high, it is difficult to detect a high-order reception wave such as a secondary reception wave because of decay of an acoustic wave. Thus, by combining these reception waves, and by detecting a temperature of the liquid material at the temperature detection section of the excitation section 37A to correct acoustic velocities VL and VS, it is possible to detect an accurate liquid level. In other words, even when one of the two methods is used, or when the two methods are combined to detect the liquid level, the detection of the liquid level by the liquid level detector is enabled only within a predetermined range between certain upper and lower limits. In the case of correcting the acoustic velocities Vl and VS, when the temperature of the liquid material cannot be directly detected, a temperature of the container may be detected to be used.

To widen the measuring range, the detected noise must be reduced. The detected noise is generated by a reflection wave or a reverberated wave in each section. For example, the detected noise is generated by reflection of an acoustic wave on a surface of the body 31. To reduce the reflected wave, a reduction in surface roughness of the inner or outer surface of the body 31 is effective. In other words, when there are concaves and convexes in the surface of the body 31, a reflected wave is generated by the concave/convex part, or the reflected wave is reverberated. Such a wave becomes a noise causing narrowing of a detectable range of the liquid surface or a reduction in detection accuracy of the liquid surface.

Thus, according to the embodiment, the surface of the body 31 is formed so that its surface roughness Ry (maximum height) can take a value equal to or less than 10 μm, preferably smaller than 1.0 μm (eg., about 0.7 μm). Such smoothness of an inner/outer surface of the container can be realized by using polishing treatment such as buffing, chemical polishing or electrolytic polishing. Especially, in the case of composite electrolytic polishing which combines mechanical polishing with the electrolytic polishing, flatness and smoothness can be simultaneously realized at a high order. To reduce an influence of a surface processed altered layer, a heat treatment such as annealing in vacuum or an inactive gas atmosphere after the polishing is preferably executed.

As shown in FIG. 5, there is a reflected wave of an acoustic wave TS propagated in the body 31, and a detected noise is generated from the reflected wave. Especially, when the body 31 is formed by bonding upper and lower cylindrical materials together, edge preparation is made by using a bonded surface of the upper and lower cylindrical materials as a mirror surface, cladding by welding is executed from the outside of the bonded part after butt welding, and an outer surface is finished to be smooth by polishing. When a fixed part 31x is formed in the body 31 by welding as described above, a reflected wave may be generated in the fixed part 31x because the fixed part 31x is different in structure from the surroundings. In other words, when welding applies heat to the fixed part 31x, the structure is influenced by the heat to be altered, and propagation characteristics of the acoustic wave TS are changed to increase the detected noise. For example, in the case of stainless steel, as a chromium carbide is deposited in a crystal grain boundary by the heat, propagation of the acoustic wave TS is disturbed to increase a reflected wave.

Therefore, according to the embodiment, a welding method of a high heat load such as tungsten inert gas welding (TIG welding) is not used, but a welding method of a low heat load such as plasma welding, electron beam welding or like is employed More preferably, without using welding, base materials are directly welded together without any joints. Furthermore, to prevent alteration of a welded part, welding is preferably carried out under reduced vacuum pressure or in an inactive gas atmosphere. Needless to say, most preferably, to make the material of the body 31 uniform, the body 31 is integrally formed without bonding processing such as welding (body 31 is formed as an molded article without bonding the upper part and the bottom 31b). In other words, most preferably, the material of the wall surface of the body 31 from the bottom of the container to a position of the liquid surface La therein is formed uniformly without any joints. For example, the integral molding of the body 31 can be carried out by drawing (deep-drawing processing).

Since the detectable range of the liquid level by the liquid level detector is limited as described above, it is not always easy to carry out liquid amount management based on the liquid level detection alone. According to the embodiment, however, by combining the liquid level measurement using the liquid level detector with the calculated value of the used liquid amount or the liquid residual amount based on the flow rate detection value, it is possible to highly accurately monitor the used liquid amount or the liquid residual amount. This is realized by a liquid amount monitoring method (described below) executed by a liquid amount monitoring program.

[Apparatus Operation]

Next, an operation of the embodiment will be described.

According to the embodiment, by executing an operation program in the control section 1X of FIG. 3, the entire apparatus can be automatically operated. For example, the operation program is stored in an internal memory of the MPU. The operation program is read from the internal memory to be executed by the arithmetic operation section. The operation programs has various operation parameters, and operation parameters should preferably be set properly by an input operation from the operation section 1P.

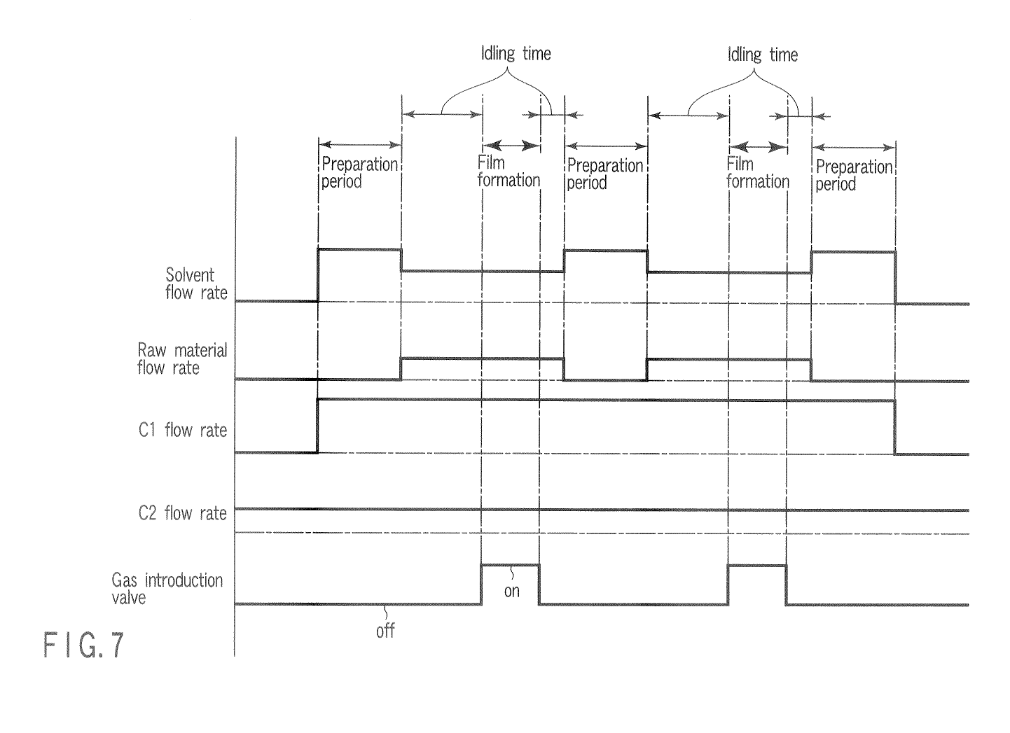

FIG. 7 is a timing chart showing an operation timing of each section of the semiconductor manufacturing apparatus 1. A solvent flow rate is a flow rate of a solvent supplied through the supply line 2X shown in FIG. 2, and controlled by the flow rate controller Xc. A raw material flow rate is a flow rate of liquid raw materials supplied through the supply lines 2A, 2B and 2C shown in FIG. 2, and controlled by the flow rate controllers Ac, Bc and Cc.

A Cl flow rate is a flow rate of a carrier gas supplied to the raw material mixing section 23 shown in FIG. 2, and controlled by the flow rate controller 22. The carrier gas is directly introduced to the gas supply line 2S. A C2 flow rate is a flow rate of a spray gas (carrier gas) supplied through the spray gas line 3T shown in FIG. 1, and controlled by a flow rate controller (not shown). Further, a gas introduction valve indicates a driving signal of the gas introduction valve 6 shown in FIG. 1.

Immediately after a start of the operation, a period (referred to as a preparation period hereinafter) for supplying a carrier gas and a solvent alone to the carburetor 3 to stabilize a distribution state and a vaporization state of the carburetor 3 as indicated by the solvent flow rate and the C1 flow rate of FIG. 7 is set. For example, a solvent flow rate is set to 1.2 ml/min (converted to 200 ml/min in gas), a C1 flow rat is set to 250 ml/min, and a C2 flow rate is set to 50 ml/min. The C2 flow rate is always constant. During the preparation period, no raw material gas is generated as no liquid raw material is supplied.

Then, as shown in FIG. 7, a period (referred to as an idling period) for supplying a liquid raw material as indicated by a raw material flow rate while reducing a solvent flow rate is set. For example, a liquid material is set to 0.5 ml/min, a solvent flow rate is set to 0.7 ml/min, and C1 and C2 flow rates are unchanged. During these preparation and idling periods, a total liquid supply amount of the solvent and the liquid material is preferably unchanged. During the idling period, a raw material gas is generated in the carburetor 3 as a liquid raw material is supplied. In this case, the gas introduction valve 6 shown in FIG. 1 is closed while the open/close valve 11 is opened, whereby the raw material gas is exhausted via the bypass exhaust line 13B.

Next, after the flow rate of the raw material gas is stabilized, a period (referred to as a deposition period) for opening the gas introduction valve 6 while closing the open/close valve 11 to introduce the raw material gas into the deposition chamber 8 is set. Then, deposition is carried out on the substrate W in the deposition chamber 8. When the set deposition time passes and a film is formed with a desired thickness, the gas introduction valve 6 is closed while the open/close valve 11 is opened, and the process returns to the idling period again. Subsequently, the supplying of the liquid raw material is stopped, and the process returns to the aforementioned preparation period. After a passage of the preparation period, by repeating a cycle of the idling period, the deposition period and the idling period again, a plurality of deposition processing steps can be sequentially carried out.

In the example shown in FIG. 7 of the embodiment, the process is finished after the execution of the two deposition processing steps. However, this example is in no way limitative. Only one deposition processing step, or three or more deposition processing steps can be repeatedly executed.

The preparation time set in the idling period can be set to a proper length, or even omitted. An example is a preparation period, an idling period, a deposition period, an idling period, a deposition period, (idling period and deposition period are repeated by optional number of times), an idling period, and a preparation period. An operation timing of each section in such a manufacturing process may be preset in the control section 1X or properly set by an operation of the operation section 1P.

After setting of the operation timing in the operation program by the operation, the control section 1X gives an instruction to the open/close valve control section 1Y and the flow rate control section 1Z to control the entire apparatus, and the aforementioned deposition step is automatically executed. The operation program contains a flow rate monitoring program for measuring used amounts or residual amounts of the solvents or the liquid materials received in the containers Xb, Ab, Bb and Cb.

By the flow rate monitoring program, a flow rate detected value (or flow rate control value) is read from each of the flow rate controllers Xc, Ac, Bc and Cc via the flow rate control section 1Z, and a used liquid amount (or liquid residual amount in the container) can be calculated from this flow rate detected value. Additionally, a liquid level detected value is read from each of the liquid level detectors Xs, As, Bs and Cs via the liquid level measuring section 1W, and a used liquid amount or a residual liquid amount can be measured from this liquid level detected value.

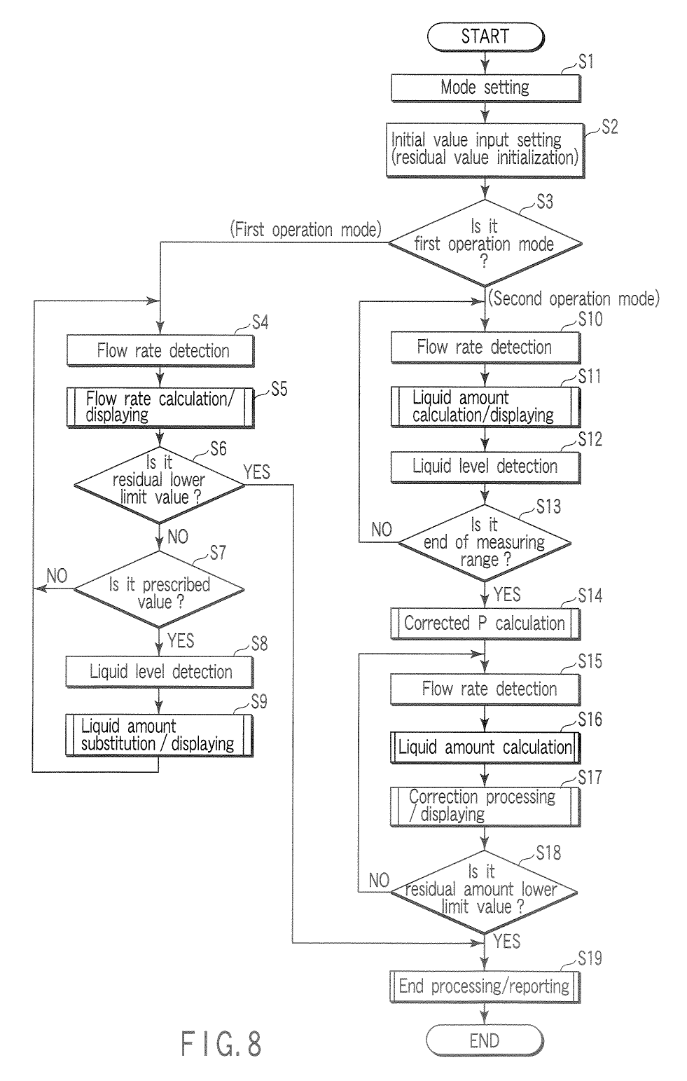

FIG. 8 is a schematic flowchart showing an example of an operation procedure of the control section using the flow rate monitoring program.

According to the flow rate monitoring program, flow rate monitoring is executed in one of a plurality of operation modes. An example in which two modes, i.e., first and second operation modes, are set will be described. The flow rate monitoring program may be configured so that an operation can be carried out in only one of operation modes below.

First, when setting of the operation mode is carried out by the operation section 1P, the set operation mode is recorded (step S1). In this case, when an initial value of a liquid amount of the container is input by the operation section 1P, initialization processing for setting an initial value of a liquid residual amount in the container as an input value is executed (step S2).

The setting of the operation mode is read, and determination is made as to whether the setting is a first operation mode (step S3). If the first operation mode is determined, the process proceeds to next step S4. On the other hand, if the setting is not the first operation mode, a second operation mode is determined, and the process proceeds to step S10 described below.

If the first operation mode is determined in step S3, a flow rate detected value or a flow rate control value is read from each of the flow rate controllers Xc, Ac, Bc and Cc via the flow rate control section 1Z (step S4). A used liquid amount or a liquid residual amount is calculated from the flow rate detected value (or flow rate setting value) to be displayed on a screen such as a monitor (step S5).

Subsequently, determination is made as to whether the used liquid amount or the liquid residual amount becomes a lower limit value before it reaches a prescribed value (step S6). If the lower limit value is reached (YES), the process proceeds to end processing (step S19) described below. On the other hand, if the lower limit value is not reached, determination is made as to whether the used liquid amount or the liquid residual amount has reached the prescribed value (step S7). If the prescribed value is determined to have been reached (YES), a liquid level detection value is read from each of the liquid level detectors Xs, As, Bs and Cs via the liquid level measuring section 1W, and a used liquid amount or a liquid residual amount is measured from this liquid level detection value (step S8). On the other hand, if the prescribed value has not been reached (NO), the process returns to step S4 to execute the processing sequentially (or for each predetermined time) until the prescribed value is reached.

Next, the used liquid amount or the liquid residual amount obtained from the flow rate detection value in the measured used liquid amount or liquid residual amount is substituted to be displayed on the screen such as the monitor (step S9). The sequence is carried out sequentially or for each predetermined time until the used liquid amount or the liquid residual amount reaches the lower limit value (container changing time) at last. Upon reaching of the lower limit value at the end, in step S6, the process proceeds to end processing (step S19). In the end processing of step S19, stop processing of the apparatus operation, or announcement processing for announcing a shortage of the liquid amount by displaying or voice is executed.

The above prescribed value is preferably set within a range to enable easy and highly accurate liquid level detection by the liquid level detector. For example, if the range is a range of a liquid level 1 to 150 mm, a used liquid amount or a liquid residual amount (e.g., liquid level 3 mm) corresponding to the liquid level within this range is set to the prescribed value. Accordingly, when a liquid level cannot be detected by the liquid level detector due to a detected noise or the like in an area (area in which liquid level is less than 1 mm, or over 150 mm) out of the range, or even when a liquid level detection error is large, liquid amount measurement more accurate than conventionally can be made in the area by correction processing based on the prescribed value. The number of prescribed values is not limited to one, but it may be plural.

Then, if the second operation mode is determined in step S3, a flow rate detection value (or flow rate control value, similar hereinafter) is read from each of the flow rate controllers Xc, Ac, Bc, and Cc via the flow rate control section 1Z (step S10). A used liquid amount is calculated from the flow rate detection value, and the used liquid value or the liquid residual amount is recorded in the internal memory or the like, and displayed on the screen such as the monitor (step S11).

A liquid level detection value is read from each of the liquid level detectors Xs, As, Bs and Cs via the liquid level measuring section 1W, and the liquid level detection value is each recorded in the internal memorv or the like (step S12). The sequence of steps S10 to S12 is repeated until a prescribed measuring range is finished (step S13). In this case, if the prescribed measuring range is finished (YES), a correction parameter is calculated based on the recording of the used liquid amount or the liquid residual amount or the recording of the liquid level detection value (step S14). On the other hand, if the prescribed measuring range is not finished (NO), the process returns to step S10 to execute similar processing.

Then, after the calculation of the correction parameter, a flow rate detection value is read from each of the flow rate controllers Xc, Ac, Bc and Cc via the flow rate controller 1Z (step S15). A used liquid amount or a liquid residual amount is calculated (step S16), and this is subjected to correction processing based on the correction parameter to be displayed on the screen such as a monitor (step S17). Then, steps S15 to S17 are repeated until the liquid residual value reaches a lower limit value (step S18). If the lower limit value is reached (YES), end processing of step S30 is executed to end the process.

For example, the aforementioned correction parameter is a parameter obtained by comparing the used liquid amount or the liquid residual amount obtained from the flow rate detection value with the liquid detection value within a prescribed measuring range. Specifically, a parameter for correcting a change mode is derived by comparing a change amount of the used liquid amount or the liquid residual amount obtained from the flow rate detection value with a change amount of the used liquid amount or the liquid residual amount measured from the liquid level detection value. For example, a relation of X and Y is represented by a linear function, in which X is a used liquid amount or a liquid residual amount obtained from a flow rate detection value, and Y is a used liquid amount or a liquid residual amount measured from the liquid level detection value. By comparing change amounts with each other within the prescribed measuring range, coefficients a and b of Y=aX+b are obtained, and these correction parameters a and b are set as correction parameters. In this case, after X is calculated, the correction parameters a and b are applied, and Y is obtained by calculating Y=aX+b to be displayed. For the correction parameters, the correction parameter a or b only may be used. A high-order function may be used in place of the linear function, and coefficients for specifying this high-order function may be set as correction parameters.

According to the apparatus of the embodiment, by the control section 1X, the used liquid amount or the liquid residual amount can be directly obtained from the liquid level detection value to be displayed on the screen such as the monitor. For example, this can be configured by operating the operation section 1P or sequentially (or periodically) automatically.

The configuration is especially effective when the liquid level detection by the liquid level detector can be executed within all the ranges necessary for liquid amount monitoring. However, even when liquid level detection is enabled within a partial range alone or when highly accurate liquid level detection is enabled within a partial range, it is preferable in that the used liquid amount or the liquid residual amount can be directly known.

The aforementioned embodiment has the following operations and effects.

According to the embodiment, by using the liquid level detector arranged in the bottom of the container to detect the liquid level of the liquid material based on the acoustic wave, the necessity of bringing the detector into direct contact with the liquid material is eliminated. Thus, it is possible to prevent a reduction in detection accuracy caused by the sticking of the liquid material to the detector, flashing of the liquid material, contamination of the liquid material and securing of chemical resistance of the detector. By detecting the liquid level of the liquid material, it is possible to accurately know the used amount of the liquid material or the residual amount of the liquid material in the container. For the liquid level detector, for example, a detector for entering an acoustic wave from the bottom to the inside, reflecting it on the liquid surface of the liquid material, and measuring the liquid level of the liquid material from detection time of its reflected wave can be used. The liquid level may be measured from a detection interval between primary and secondary reflected waves of the acoustic wave by the liquid surface. Additionally, the liquid level detector is preferably disposed in a closely contact state with the bottom of the container from the outside.

According to the embodiment, the used liquid amount or the liquid residual amount is calculated from the flow rate of the liquid supply line, and the calculated value of the used liquid amount or the liquid residual amount is corrected based on the liquid level (liquid level detection value) detected by the liquid level detector. Accordingly, in the liquid level detector, the liquid level detectable range or the range of highly accurately detecting the liquid level may be narrower than that necessary for knowing the used liquid amount or the liquid residual amount. According to the embodiment, however, by correcting the used liquid amount or the liquid residual amount based on the liquid level detection value obtained within a predetermined range, it is possible to know the used liquid amount or the liquid residual amount more accurately than conventionally even outside the liquid level detectable range or the highly accurate detectable range.

The liquid amount correction means of the embodiment makes correction when the used liquid amount or the liquid residual amount reaches the prescribed value. In this case, by presetting the prescribed range within the detectable range or the highly accurate detectable range of the liquid level detector, the correction is surely carried out. To correct the used liquid amount or the liquid residual amount based on the sequential correction parameters, the frequency of liquid level detection can be reduced, and it is possible to maintain certain accuracy of the used liquid amount or the liquid residual amount after a passage of time from correction parameter acquisition by the liquid level detection.

The liquid amount correction means of the embodiment, the change amount of the used liquid amount or the liquid residual amount within the prescribed range of the used liquid amount or the liquid residual amount is compared with that of the liquid level detection value to calculate a correction parameter. Accordingly, as a difference between change rates can be used as a correction parameter, it is possible to prevent an increase in shifting of the used liquid amount or the liquid residual amount with a passage of time, and to maintain high accuracy even after the passage of time from the correction parameter acquisition by the liquid level detection.

According to the embodiment, by using the liquid level detector arranged in the bottom of the container, the liquid level of the liquid material can be detected based on the acoustic wave. Thus, as the necessity of bringing the detector into direct contact with the liquid material is eliminated, it is possible to prevent a reduction in detection accuracy caused by sticking of the liquid material to the detector, flashing of the liquid material, contamination of the liquid material and securing of the chemical resistance of the detector. Moreover, as the liquid level of the liquid material can be detected, it is possible to accurately know the used amount of the liquid material or the residual amount of the liquid material in the container.

For the liquid level detector, for example, the detector for entering the acoustic wave from the bottom of the container therein, reflecting it on the liquid surface of the liquid material, and measuring the liquid level of the liquid material from the detection time of its reflected wave can be used. The liquid level may be measured from the detection interval between the primary and secondary reflected waves of the acoustic wave by the liquid surface. Further, the liquid level detector is preferably installed in the bottom of the container a sealed state from the outside.

According to the embodiment, in the case of calculating the used liquid amount or the liquid residual amount based on the flow rate of the liquid supply line, the liquid level of the liquid material is detected based on the acoustic wave by using the liquid level detector arranged in the bottom of the container. By correcting the liquid used amount or the liquid residual amount based on the liquid level detection value, it is possible to accurately know the used amount of the liquid material or the residual amount of the liquid material in the container. In the liquid level detector, the detectable range of the liquid level or the highly accurate detection range may be narrower than that necessary for knowing the used liquid amount or the liquid residual amount. However, according to the present invention, by correcting the used liquid amount or the liquid residual amount within the detectable range of the liquid level or the highly accurate detectable range, it is possible to know the used liquid amount or the liquid residual amount more accurately than conventionally even outside the detectable range of the liquid level or the highly accurate detectable range.

As compared with the conventional apparatus or method, the present invention has the following advantages.

(1) The semiconductor manufacturing apparatus is configured such that the liquid level detector for detecting the liquid level by using the acoustic wave is arranged in the bottom of the container, and can detect the liquid level in noncontact with the liquid material. Accordingly, since the actual residual amount of the liquid material in the container can be accurately detected, and shifting of the residual amount estimated value can be prevented by properly checking the actual liquid surface, it is possible to reduce wastes of very expensive liquid materials, and to reduce semiconductor manufacturing costs.

(2) The liquid surface of the liquid material received in the container is detected by the liquid level detector. Thus, as compared with the conventional method for calculating the used liquid amount or the residual liquid amount based on the flow rate detection value, it is possible to monitor the liquid amount more surely and accurately. Especially, since cumulative calculation errors can be eliminated as compared with the conventional method, it is possible to greatly reduce a liquid material discarded amount. Cost effects are high when the liquid material is expensive or discarding processing is difficult.

(3) Even when the measurable range or the highly accurate detectable range of the liquid level detector is limited to a certain extent, it is possible to monitor the liquid amount in a wide range by calculating the used liquid amount or the liquid residual amount based on the flow rate detection value. In other words, it is possible to reduce a calculation error of the used liquid amount or the liquid residual amount based on the flow rate detection value by the correction processing based on the liquid level detection value of the liquid level detector, and to compensate for the detection range limit of the liquid level detector by calculating the used liquid amount or the liquid residual amount based on the flow rate detection value.

(4) Furthermore, contamination of the liquid material by the sensor structure can be prevented, countermeasures caused by chemical resistance to prevent corrosion of the liquid material by the sensor structure are made unnecessary, a reduction in detection accuracy caused by sticking of the material to the sensor structure can be prevented, and safety with respect to the easily flashed liquid material (e.g., the organic solvent) can be improved. Thus, as compared with the conventional liquid surface sensor brought into contact with the liquid material, it is possible to improve material quality, to facilitate dealing with material characteristics, to improve safety, and to achieve high detection accuracy.

According to the present invention, the actual residual amount of the liquid material received in the container can be accurately known, and the residual amount is suppressed minimum to prevent waste of the expensive material. Therefore, the present invention is highly advantageous in that semiconductor manufacturing costs can be suppressed.

The semiconductor manufacturing apparatus, the liquid amount monitoring apparatus, and the liquid amount monitoring method of the present invention are not limited to aforementioned illustrated examples. Needless to say, various changes can be made without departing from the spirit and scope of the present invention.

1. A semiconductor manufacturing apparatus characterized by comprising:
a liquid material supply section which includes a container to receive a liquid material and supplies the liquid material from the container;
a liquid vaporizing section which vaporizes the liquid material supplied from the liquid material supply section to generate a gas;
a processing section which executes processing by using the gas supplied from the liquid vaporizing section;
an exhaust section which exhausts the gas from the processing section; and
liquid level detection means arranged in a bottom of the container to introduce an acoustic wave into the liquid material and to detect a liquid level of the liquid material from a reflected wave reflected on a liquid surface.

2. The semiconductor manufacturing apparatus according to claim 1, characterized in that the liquid level detection means includes an excitation section constituted of a piezoelectric vibrator to introduce the acoustic wave into the liquid material, and a temperature detection section incorporated in the excitation section.

3. The semiconductor manufacturing apparatus according to claim 1, characterized in that the liquid material supply section includes:
a liquid supply line connected to the container to receive the liquid material;
a flow rate controller or a flow rate detector disposed in the midway of the liquid supply line;
a liquid level detector arranged in the bottom of the container to introduce the acoustic wave into the liquid material and to detect the liquid level of the liquid material from the reflected wave reflected on the liquid surface;
liquid amount calculation means for calculating a used liquid amount or a liquid residual amount in the container based on a flow rate setting value for the flow rate controller or a flow rate detection value by the flow rate detector; and
liquid amount correction means for correcting the used liquid amount or the liquid residual amount calculated by the liquid amount calculation means based on the liquid level detection value detected by the liquid level detector.

4. The semiconductor manufacturing apparatus according to claim 3 characterized in that the liquid amount correction means is means for updating the used liquid amount or the liquid residual amount to a value derived based on the liquid level detection value.

5. The semiconductor manufacturing apparatus according to claim 3 or 4, characterized in that the liquid amount correction means executes the correction when the used liquid amount or the liquid residual amount reaches a prescribed value.

6. The semiconductor manufacturing apparatus according to claim 3, characterized in that the liquid amount correction means first calculates a correction parameter based on the used liquid amount or the liquid residual amount and the liquid level detection value, and then applies the correction parameter to the used liquid amount or the liquid residual amount to execute the correction.

7. The semiconductor manufacturing apparatus according to claim 6, characterized in that the liquid amount correction means compares a change amount of the used liquid amount or the liquid residual amount within a prescribed range of the used liquid amount or the liquid residual amount with a change amount of the liquid level detection value to calculate the correction parameter.

8. The semiconductor manufacturing apparatus according to claim 1, characterized in that the container includes a first body part and a second body part matched with each other, and the matched abut parts are joined together by welding means.

9. The semiconductor manufacturing apparatus according to claim 8, characterized in that the welding means uses one of plasma welding or electron beam welding.

10. The semiconductor manufacturing apparatus according to claim 8, characterized in that surface roughness of each of the first body part and the second body part is equal to or less than 10 μm.

11. The semiconductor manufacturing apparatus according to claim 1, characterized in that the container is formed by Pointless integral molding.

12. The semiconductor manufacturing apparatus according to claim 2, characterized in that the liquid material is an organic metal material.

13. The semiconductor manufacturing apparatus according to claim 12, characterized in that the organic metal material is a high dielectric thin-film material.

14. A liquid amount monitoring apparatus characterized by comprising:
a container to receive a liquid material;
a liquid supply line connected to the container;
a flow rate controller or a flow rate detector disposed in the midway of the liquid supply line;
a liquid level detector arranged in a bottom of the container to introduce the acoustic wave into the liquid material and to detect a liquid level of the liquid material from a reflected wave reflected on a liquid surface;
liquid amount calculation means for calculating a used liquid amount or a liquid residual amount in the container based on a flow rate setting value for the flow rate controller or a flow rate detection value by the flow rate detector; and
liquid amount correction means for correcting the used liquid amount or the liquid residual amount calculated by the liquid amount calculation means based on the liquid level detection value detected by the liquid level detector.

15. The liquid amount monitoring apparatus according to claim 14, characterized in that the liquid amount correction means is means for updating the used liquid amount or the liquid residual amount to a value derived based on the liquid level detection value.

16. The liquid amount monitoring apparatus according to claim 14 or 15, characterized in that the liquid amount correction means executes the correction when the used liquid amount or the liquid residual amount reaches a prescribed value.

17. The liquid amount monitoring apparatus according to claim 14, characterized in that the liquid amount correction means first calculates a correction parameter based on the used liquid amount or the liquid residual amount and the liquid level detection value, and then applies the correction parameter to the used liquid amount or the liquid residual amount to execute the correction.

18. The liquid amount monitoring apparatus according to claim 17, characterized in that the liquid amount correction means compares a change amount of the used liquid amount or the liquid residual amount within a prescribed range of the used liquid amount or the liquid residual amount with a change amount of the liquid level detection value to calculate the correction parameter.

19. A liquid amount monitoring method of a semiconductor manufacturing apparatus which sends a liquid material from a container to receive the liquid material and vaporizes the liquid material to generate a gas, and sends the gas to a processing section to execute processing, characterized by introducing an acoustic wave from a bottom of the container into the liquid material, detecting a liquid level of the liquid material from a reflected wave reflected on a liquid surface, and using a detected liquid level detection value to check a residual amount of the liquid material in the container.

20. A liquid amount monitoring method for monitoring a liquid in a container in a process of supplying the liquid via a liquid supply line connected to the container to receive the liquid,
characterized by calculating a used liquid amount or a liquid residual amount in the container based on a flow rate of the liquid through the liquid supply line, arranging a liquid level detector to detect a liquid level of the liquid based on an acoustic wave in a bottom of the container, and correcting the used liquid amount or the liquid residual amount based on a liquid level detection value detected by the liquid level detector.

21. The liquid amount monitoring method according to claim 20, characterized in that the used liquid amount or the liquid residual amount is updated to a value derived based on the liquid level detection value to be corrected.

22. The liquid amount monitoring method according to claim 20 or 21, characterized in that the used liquid amount or the liquid residual amount is corrected when a prescribed value is reached.

23. The liquid amount monitoring method according to claim 20, characterized by first calculating a correction parameter based on the used liquid amount or the liquid residual amount and the liquid detection value, and then applying the correction parameter to the used liquid amount or the liquid residual amount to execute the correction.

24. The liquid amount monitoring method according to claim 23, characterized in that the correction parameter is calculated by comparing a change value of the used liquid amount or the liquid residual amount within a prescribed range with a change value of the liquid level detection value.
